(19) United States
(12) Patent Application Publication
(10) Pub. No.: US 2026/0201200 A1
(43) Pub. Date: Jul. 16, 2026

(54) TEXTURING ADDITIVE FOR IMPROVING EFFICIENCY OF SOLAR CELL AND PREPARATION METHOD AND USE THEREOF

(71) Applicants: Gengxin HAN, Friescovita, TX (US); Bing HAN, Friescovita, TX (US)

(72) Inventors: Gengxin HAN, Friescovita, TX (US); Bing HAN, Friescovita, TX (US)

(21) Appl. No.: 19/243,274

(22) Filed: Jun. 19, 2025

(30) Foreign Application Priority Data
Jan. 10, 2025 (CN) 202510041089.4

(51) Int. Cl. C09D 139/06; C09D 7/45; C09D 7/61; C09D 7/63; C09D 7/65; H10F 77/70

(52) U.S. Cl. CPC C09D 139/06; C09D 7/45; C09D 7/61; C09D 7/63; C09D 7/65; H10F 77/70

(57) ABSTRACT

The present disclosure discloses a texturing additive for improving efficiency of a solar cell, and a preparation method and a use thereof. The texturing additive includes the following components in percentages by mass: 0.01% to 0.1% of a primary nucleating agent, 0.05% to 0.2% of a secondary nucleating agent, 0.05% to 0.5% of a dispersant, 0.5% to 1% of an etching inhibitor, and a balance of water. The additive of the present disclosure can effectively regulate a rate of a reaction between an alkaline solution and a silicon wafer, reduce the surface tension of the texturing etching solution, and facilitate rapid detachment of hydrogen bubbles generated during the texturing reaction from the silicon wafer surface, thereby inducing the formation of a more uniform, regular, and denser pyramid structure on the silicon wafer surface.

### CROSS REFERENCE TO THE RELATED APPLICATIONS

This application is based upon and claims priority to Chinese Patent Application No. 202510041089.4, filed on Jan. 10, 2025, the entire contents of which are incorporated herein by reference.

### TECHNICAL FIELD

The present disclosure is applied in the field of photovoltaic cell production and manufacturing, and specifically relates to a texturing additive for improving efficiency of a solar cell, and a preparation method and a use thereof.

### BACKGROUND

The texturing treatment of a surface of a silicon wafer is a main part in the production of a photovoltaic cell. The main objective of this treatment is to conduct a texturing reaction on the surface of the silicon wafer, to form a layer of uneven pyramid-shaped textured surface structure on the surface of the silicon wafer. This structure increases the surface area of the silicon wafer, and meanwhile produces a significant light-trapping effect, thereby reducing the reflectivity of the surface of the silicon wafer and allowing more sunlight to be absorbed by the silicon wafer. Among the textured pyramid structures, incident light undergoes multiple reflections, significantly increasing the interaction between the light and the cell, and enhancing the collection of photo-generated carriers, thereby improving the conversion efficiency of the cell.

In a texturing process, pyramid structures are etched on the surface of the silicon wafer mainly through chemical corrosion (mainly by an alkaline or acidic solution). Considering that monocrystalline silicon has a regular crystal structure, the texturing of monocrystalline silicon often adopts an alkaline solution such as sodium hydroxide (NaOH) or potassium hydroxide (KOH) as an etching solution for the texturing reaction. During the texturing reaction, since Si (100) crystal plane has more dangling bonds than Si (111) crystal plane, the etching rate of OH⁻ on the Si (100) crystal plane is relatively high. Therefore, the anisotropic etching of the silicon wafer by OH⁻ on different crystal planes leads to the formation of a large number of pyramid structures on the surface of the silicon wafer. A texturing additive can control the etching reaction rate of the alkaline solution on different crystal planes of silicon to form a uniform and dense pyramid-shaped textured surface structure on the surface of the silicon wafer. In addition, the texturing additive can also significantly shorten the texturing time and reduce the alkali consumption during the reaction process. However, the existing texturing additives commercially available suffer from inconsistent pyramid sizes and elevated fragmented texture rates on the textured surface after texturing. These problems may lead to an increase in surface defects of the silicon wafer, thereby damaging the contact effect between the textured surface and the passivation layer in a subsequent process, and affecting the uniformity of the coating, resulting in a loss of cell efficiency.

### SUMMARY

Objective of the present disclosure: In order to solve the above problems, the present disclosure provides a texturing additive for improving efficiency of a solar cell, and a preparation method and a use thereof. The texturing additive can more precisely control a rate of the contact reaction between the alkali and the silicon wafer surface, effectively reduce the surface tension at the reaction interface, facilitate rapid detachment of bubbles generated by the reaction, and help to form a more uniform, regular, and denser pyramid structure on the silicon wafer surface. The textured surface of the silicon wafer obtained through the texturing additive of the present disclosure for the texturing reaction is more uniform, with lower reflectivity, better adaptability to subsequent processes, and higher conversion efficiency.

Technical solutions: In order to achieve the objective of the present disclosure, technical solutions adopted in the present disclosure include:

A texturing additive for improving efficiency of a solar cell includes components in percentages by mass as follows:

0.01% to 0.1% of a primary nucleating agent, 0.05% to 0.2% of a secondary nucleating agent, 0.05% to 0.5% of a dispersant, 0.5% to 1% of an etching inhibitor, and a balance of water, where the primary nucleating agent is a copolymer containing a vinylpyrrolidone structural unit, and the secondary nucleating agent is a compound containing a nitrobenzene structure.

Preferably, the texturing additive includes components in percentages by mass as follows:

0.02% to 0.06% of the primary nucleating agent, 0.05% to 0.15% of the secondary nucleating agent, 0.1% to 0.2% of the dispersant, 0.5% to 0.8% of the etching inhibitor, and the balance of water.

Asa specific embodiment, the primary nucleating agent has a structural formula as follows:

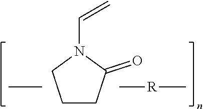

where, R is selected from a group consisting of structural units of vinyl alcohol, styrene, vinylimidazole, hexadecene, isopropylacrylamide, methacrylamide, acrylamide, methyl methacrylate, acrylic acid, vinyl acetate, butyl acrylate, methacrylic acid, and maleic anhydride; n in the structural formula represents a number of the vinylpyrrolidone structural unit in the copolymer, and a molecular weight of the copolymer ranges from 20,000 g/mol to 1,000,000 g/mol.

As a specific embodiment, the secondary nucleating agent has a structural formula as follows:

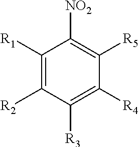

where, R₁, R₂, R₃, R₄, and R₅ are each independently selected from a group consisting of H, halogen, alkyl, alkoxy, amino, amido, aldehyde, hydrazinyl, sulfonic acid/sulfonate, phenol/phenolate, carboxyl, and ester groups.

Further, the R₁, the R₂, the R₃, the R₄, and the R₅ are each independently selected from a group consisting of H, halogen, C₁-C₁₀ alkyl, —NH₂, —(CH₂)ₘCONH₂, —(CH₂)ₚCHO, —NHNH₂, —SO₃R₆, —OR₇, and —COOR₈, where the m and the p are each a natural number, m is 0 to 5, and p is 0 to 5; the R₆ is selected from a group consisting of H and a metal atom, and the R₇ and the R₈ are each independently selected from a group consisting of H, a metal atom, and C₁-C₅ alkyl.

Preferably, the R₁, the R₂, the R₃, the R₄, and the R₅ are each independently selected from a group consisting of H, halogen, C₁-C₃ alkyl, —NH₂, —CONH₂, —CHO, —NHNH₂, —SO₃R₆, —OR₇, and —COOR₈; the R₆ is selected from a group consisting of H, Na, and K; the R₇ and the R₈ are each independently selected from a group consisting of H, Na, K, and C₁-C₂ alkyl; and at least three of the R₁, the R₂, the R₃, the R₄, and the R₅ are H.

As a specific embodiment, the dispersant is one of, or a combination of two or more of sodium lignosulfonate, alkyl polyglucoside, sodium polymethacrylate, sulfonated polystyrene, polyvinyl alcohol, sodium polyacrylate, and a polysaccharide-based compound, where a structural formula of the polysaccharide-based compound is (C₆H₁₀O₅)ₘ, and in the structural formula, the C₆H₁₀O₅ represents a monosaccharide unit with one water molecule removed, and the n represents a number of the monosaccharide unit in the polysaccharide-based compound.

Preferably, the polysaccharide-based compound is selected from a group consisting of maltose, carrageenan, starch, lactose, cellulose, chitin, xanthan gum, inulin, polymannose, and polyxylose.

As a specific embodiment, the etching inhibitor is one of, or a combination of two or more of sodium chloride, sodium dihydrogen phosphate, sodium carbonate, sodium citrate, sodium acetate, and sodium silicate.

The present disclosure further provides a preparation method of the texturing additive for improving the efficiency of the solar cell, including the following steps:
according to the percentages by mass, adding the primary nucleating agent, the secondary nucleating agent, the dispersant, and the etching inhibitor to water, and uniformly mixing under stirring to obtain the texturing additive.

The present disclosure further provides a use of the texturing additive in texturing of a silicon wafer.

As a specific embodiment, the texturing additive is used in a texturing reaction of the silicon wafer to improve efficiency of a solar cell.

As a specific embodiment, the use includes:
step (1) dissolving a pure alkali in water and uniformly mixing to obtain an alkali solution, and adding the texturing additive to the alkali solution and uniformly mixing to formulate a mixed texturing agent; and
step (2) immersing the silicon wafer in the mixed texturing agent for the texturing reaction.

As a further embodiment:
In the step (1), the pure alkali is selected from a group consisting of NaOH and KOH; a mass concentration of the alkali solution is 0.5% to 1%; and a mass ratio of the texturing additive to the alkali solution is (0.3 to 0.8):100; and
in the step (2), the texturing reaction is conducted at a temperature controlled between 75° C. and 85° C. for 350 s to 450 s.

Beneficial effects: Compared with the prior art, the present disclosure has the following advantages:
(1) During the texturing reaction of the solar cell, the use of the texturing additive of the present disclosure can effectively control the rate of the contact reaction between the alkali and the silicon wafer surface, increase the surface coverage of the reaction, reduce the surface tension at the reaction interface, and facilitate the rapid detachment of bubbles generated by the reaction, thereby increasing the number of nucleation sites on the silicon wafer surface, and thus forming a more uniform, regular and denser pyramid structure.
(2) The textured surface of the silicon wafer obtained through the texturing additive of the present disclosure for texturing reaction is more uniform, with lower reflectivity, better adaptability to subsequent processes, and higher conversion efficiency.
(3) In the present disclosure, the secondary nucleating agent mainly functions to enhance the adsorption capacity of the primary nucleating agent on the silicon wafer surface, allowing the nucleating agent molecules to be densely and uniformly spread on the silicon wafer surface and to induce the formation of nucleation network sites. Therefore, the synergistic effect of the primary nucleating agent and the secondary nucleating agent makes the nucleation process more uniform and efficient, which is conducive to forming a denser and more uniform pyramid structure.

### BRIEF DESCRIPTION OF THE DRAWINGS

FIG. 1 shows a microscopic image of a textured surface of a silicon wafer obtained through the texturing reaction in Example 1.

FIG. 2 shows a microscopic image of a textured surface of a silicon wafer obtained through the texturing reaction in Comparative Example 1.

### DETAILED DESCRIPTION OF THE EMBODIMENTS

The present disclosure is further described by the following examples. These examples are entirely exemplary, and are intended only to specifically describe the present disclosure and should not be construed as limiting the present disclosure. The present disclosure is further described below in detail in combination with the appended drawings and examples.

### Example 1

Formulation of an additive: The additive was formulated by uniformly mixing 0.06 mass % of a vinylpyrrolidone-styrene copolymer (with a molecular weight of 21,500 g/mol) as a primary nucleating agent, 0.05 mass % of sodium p-nitrobenzenesulfonate as a secondary nucleating agent, 0.2 mass % of alkyl polyglucoside as a dispersant, 0.5 mass % of sodium chloride as an etching inhibitor, and the balance of deionized water.

30 L of deionized water was added into a 40 L texturing reaction tank and heated to 82° C. Then 150 g of NaOH was added into the texturing reaction tank to obtain a mixture. The mixture was stirred until dissolved to obtain a 0.5% alkali solution. Then 100 g of the additive formulated above was added to the alkali solution, and uniformly mixed to formulate a mixed texturing agent. A silicon wafer was immersed into the texturing reaction tank to undergo a texturing reaction for 420 s. After the texturing reaction, the silicon wafer was dried and subjected to a characterization analysis.

### Example 2

The additive and the mixed texturing agent were prepared according to the method of Example 1 to conduct the texturing reaction, except that the additive was formulated by uniformly mixing 0.02 mass % of a vinylpyrrolidone-vinyl alcohol copolymer (with a molecular weight of 31,000 g/mol) as the primary nucleating agent, 0.15 mass % of sodium 3-nitrobenzoate as the secondary nucleating agent, 0.1 mass % of maltose as the dispersant, 0.8 mass % of sodium citrate as the etching inhibitor, and the balance of deionized water.

### Example 3

The additive and the mixed texturing agent were prepared according to the method of Example 1 to conduct the texturing reaction, except that the additive was formulated by uniformly mixing 0.03 mass % of a vinylpyrrolidone-vinyl acetate copolymer (with a molecular weight of 39,400 g/mol) as the primary nucleating agent, 0.06 mass % of sodium 2-methoxy-5-nitrophenolate as the secondary nucleating agent, 0.1 mass % of sodium lignosulfonate as the dispersant, 0.6 mass % of sodium dihydrogen phosphate as the etching inhibitor, and the balance of deionized water.

### Example 4

The additive and the mixed texturing agent were prepared according to the method of Example 1 to conduct the texturing reaction, except that the additive was formulated by uniformly mixing 0.04 mass % of a vinylpyrrolidone-acrylamide copolymer (with a molecular weight of 109,200 g/mol) as the primary nucleating agent, 0.1 mass % of 2-nitroaniline as the secondary nucleating agent, 0.15 mass % of sodium polyacrylate as the dispersant, 0.7 mass % of sodium acetate as the etching inhibitor, and the balance of deionized water.

### Example 5

The additive and the mixed texturing agent were prepared according to the method of Example 1 to conduct the texturing reaction, except that the additive was formulated by uniformly mixing 0.02 mass % of a vinylpyrrolidone-vinylimidazole copolymer (with a molecular weight of 164,000 g/mol) as the primary nucleating agent, 0.12 mass % of sodium 3-nitrobenzoate as the secondary nucleating agent, 0.18 mass % of chitin as the dispersant, 0.6 mass % of sodium carbonate as the etching inhibitor, and the balance of deionized water.

### Example 6

The additive and the mixed texturing agent were prepared according to the method of Example 1 to conduct the texturing reaction, except that the additive was formulated by uniformly mixing 0.03 mass % of a vinylpyrrolidone-methyl methacrylate copolymer (with a molecular weight of 738,500 g/mol) as the primary nucleating agent, 0.07 mass % of sodium 2-nitroaniline-4-sulfonate as the secondary nucleating agent, 0.19 mass % of polyvinyl alcohol as the dispersant, 0.8 mass % of sodium dihydrogen phosphate as the etching inhibitor, and the balance of deionized water.

### Example 7

The additive and the mixed texturing agent were prepared according to the method of Example 1 to conduct the texturing reaction, except that the additive was formulated by uniformly mixing 0.05 mass % of a vinylpyrrolidone-maleic anhydride copolymer (with a molecular weight of 522,500 g/mol) as the primary nucleating agent, 0.09 mass % of p-nitrobenzoic acid as the secondary nucleating agent, 0.2 mass % of polymannose as the dispersant, 0.5 mass % of sodium acetate as the etching inhibitor, and the balance of deionized water.

### Comparative Example 1

The additive and the mixed texturing agent were prepared according to the method of Example 1 to conduct the texturing reaction, except that the additive used herein was a conventional texturing additive (Shichuang V-Series texturing additive) commercially available on the current market.

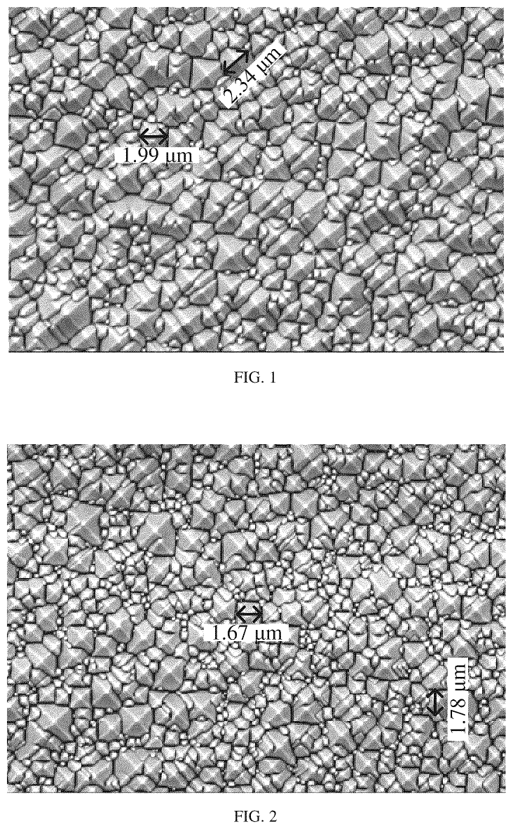

A microscopic image of the textured surface of the silicon wafer obtained by Example 1 is shown in FIG. 1, and a microscopic image of the textured surface of the silicon wafer obtained by Comparative example 1 is shown in FIG. 2. The pyramid size distribution data of the textured surfaces obtained by the reactions of Examples 1 to 7 and Comparative example 1 is shown in Table 1, and their reflectivity data is shown in Table 2. Combining the data in Table 1 and Table 2 and comparing FIG. 1 with FIG. 2, it can be concluded that the silicon wafer prepared by the conventional commercial texturing additive exhibits non-uniform pyramid size distribution on the surface, with a high proportion of small-sized pyramids, significant tiny fragmented textures on the surface, and elevated reflectivity. In contrast, the surface of the silicon wafer made by the texturing additive of present disclosure demonstrates improved pyramid uniformity, markedly diminished fragmented textures, and lower reflectivity.

TABLE 1

| Pyramid | | | | | | | |
|---|---|---|---|---|---|---|---|
| size range | | | | | | | |
| (μm) | 0.1-0.5 | 0.5-1.0 | 1.0-1.5 | 1.5-2.0 | 2.0-2.5 | 2.5-3.0 | 3.0-3.5 |
| Number of | 2 | 26 | 93 | 163 | 105 | 12 | 3 |
| pyramids in | | | | | | | |
| Example 1 | | | | | | | |
| Number of | 3 | 15 | 113 | 178 | 98 | 16 | 2 |
| pyramids in | | | | | | | |
| Example 2 | | | | | | | |
| Number of | 8 | 13 | 125 | 185 | 112 | 21 | 5 |
| pyramids in | | | | | | | |
| Example 3 | | | | | | | |
| Number of | 6 | 19 | 106 | 192 | 107 | 21 | 6 |
| pyramids in | | | | | | | |
| Example 4 | | | | | | | |
| Number of | 5 | 23 | 97 | 183 | 102 | 18 | 1 |
| pyramids in | | | | | | | |
| Example 5 | | | | | | | |
| Number of | 7 | 25 | 103 | 193 | 95 | 17 | 3 |
| pyramids in | | | | | | | |
| Example 6 | | | | | | | |
| Number of | 2 | 21 | 109 | 186 | 110 | 11 | 5 |
| pyramids in | | | | | | | |
| Example 7 | | | | | | | |
| Number of | 53 | 76 | 112 | 146 | 65 | 23 | 2 |
| pyramids in | | | | | | | |
| Comparative | | | | | | | |
| example 1 | | | | | | | |

TABLE 2

| Additive | Reflectivity (%) |
|---|---|
| Example 1 | 8.24 |
| Example 2 | 7.97 |
| Example 3 | 8.13 |
| Example 4 | 8.09 |
| Example 5 | 8.15 |
| Example 6 | 7.93 |
| Example 7 | 8.02 |
| Comparative | 9.17 |
| example 1 | |

### Example 8

Formulation of an additive: The additive was formulated by uniformly mixing 0.06 mass % of a vinylpyrrolidone-styrene copolymer (with a molecular weight of 21,500 g/mol) as a primary nucleating agent, 0.05 mass % of sodium p-nitrobenzenesulfonate as a secondary nucleating agent, 0.2 mass % of alkyl polyglucoside as a dispersant, 0.5 mass % of sodium chloride as an etching inhibitor, and the balance of deionized water.

450 L of deionized water was added into a 500 L texturing reaction tank and heated to 76° C. Then 3.38 L of a 45 wt % NaOH solution was added into the texturing reaction tank to obtain a mixture. The mixture was uniformly mixed to obtain a 0.5% alkali solution. Then 1.5 L of the additive formulated above was added to the alkali solution and uniformly mixed via in-tank circulation to formulate a mixed texturing agent. A silicon wafer was immersed into the texturing reaction tank to undergo a texturing reaction for 380 s. After the texturing reaction, the silicon wafer was advanced to a subsequent cell fabrication process, and a cell was finally made. Electrical performance indexes and reflectivity of the cell were tested.

### Comparative Example 2

450 L of deionized water was added into a 500 L texturing reaction tank and heated to 76° C. Then 3.38 L of a 45 wt % NaOH solution was added into the texturing reaction tank to obtain a mixture. The mixture was uniformly mixed to obtain a 0.5% alkali solution. Then the conventional texturing additive (Shichuang V-Series texturing additive) commercially available on the current market was added to the alkali solution and uniformly mixed via in-tank circulation to formulate a mixed texturing agent. A silicon wafer was immersed into the texturing reaction tank to undergo a texturing reaction for 380 s. After the texturing reaction, the silicon wafer was advanced to a subsequent cell fabrication process, and a cell was finally made. Electrical performance indexes and reflectivity of the cell were tested.

Table 3 shows average electrical performance data and reflectivity of 1200 cells obtained through the texturing reactions in Example 8 and Comparative Example 2. According to the data in Table 3, it is demonstrated that, the cells prepared using the texturing additive of the present disclosure have effectively reduced reflectivity, improved fill factors and short-circuit current, and an increase in the average cell conversion efficiency of about 0.45%, compared with the conventional texturing additive. This is mainly attributed to the fact that a more uniform textured surface can improve contact passivation effects in the subsequent coating processes, thereby improving the overall efficiency of the cells to some extent.

TABLE 3

| | | Open-circuit | Short-circuit | Fill | Reflec- |
|---|---|---|---|---|---|
| | Efficiency | voltage | current | factor | tivity |
| Additive | (η, %) | (Voc) | (Isc) | (FF) | (%) |
| Example 8 | 26.97 | 0.7362 | 14.352 | 86.52 | 8.16 |
| Comparative | 26.52 | 0.7358 | 14.125 | 86.13 | 9.24 |
| example 2 | | | | | |

The foregoing description merely illustrates representative embodiments of the present disclosure and does not limit the protection scope of the present disclosure. It is to be emphasized that, any modifications and optimizations made by those skilled in the art without departing from the technical principles of the present disclosure shall be deemed to fall within the protection scope of the present disclosure.

1. A texturing additive for improving efficiency of a solar cell, wherein the texturing additive comprises components in percentages by mass as follows: 0.01% to 0.1% of a primary nucleating agent, 0.05% to 0.2% of a secondary nucleating agent, 0.05% to 0.5% of a dispersant, 0.5% to 1% of an etching inhibitor, and a balance of water; the primary nucleating agent is a copolymer containing a vinylpyrrolidone structural unit, and the secondary nucleating agent is a compound containing a nitrobenzene structure.

2. The texturing additive for improving the efficiency of the solar cell according to claim 1, wherein the primary nucleating agent has a structural formula as follows: 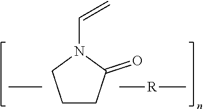
wherein, R is selected from a group consisting of structural units of vinyl alcohol, styrene, vinylimidazole, hexadecene, isopropylacrylamide, methacrylamide, acrylamide, methyl methacrylate, acrylic acid, vinyl acetate, butyl acrylate, methacrylic acid, and maleic anhydride; the n in the structural formula represents a number of the vinylpyrrolidone structural unit in the copolymer, and a molecular weight of the copolymer ranges from 20,000 g/mol to 1,000,000 g/mol.

3. The texturing additive for improving the efficiency of the solar cell according to claim 1, wherein the secondary nucleating agent has a structural formula as follows: 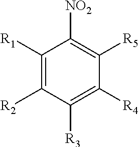
wherein, R₁, R₂, R₃, R₄, and R₅ are each independently selected from a group consisting of H, halogen, alkyl, alkoxy, amino, amido, aldehyde, hydrazinyl, sulfonic acid, sulfonate, phenol, phenolate, carboxyl, and ester groups.

4. The texturing additive for improving the efficiency of the solar cell according to claim 3, wherein the R₁, the R₂, the R₃, the R₄, and the R₅ are each independently selected from a group consisting of H, halogen, C₁-C₁₀ alkyl, —NH₂, —(CH₂)ₘCONH₂, —(CH₂)ₚCHO, —NHNH₂, —SO₃R₆, —OR₇, and —COOR₈, wherein the m and the p are each a natural number, the m is 0 to 5, and the p is 0 to 5, the R₆ is selected from a group consisting of H and a metal atom, and the R₇ and the R₈ are each independently selected from a group consisting of H, a metal atom, and C₁-C₅ alkyl.

5. The texturing additive for improving the efficiency of the solar cell according to claim 1, wherein the dispersant is one of, or a combination of two or more of sodium lignosulfonate, alkyl polyglucoside, sodium polymethacrylate, sulfonated polystyrene, polyvinyl alcohol, sodium polyacrylate, and a polysaccharide-based compound, wherein a structural formula of the polysaccharide-based compound is (C₆H₁₀O₅)ₘ, the C₆H₁₀O₅ represents a monosaccharide unit with one water molecule removed, and the n represents a number of the monosaccharide unit in the polysaccharide-based compound; and
the etching inhibitor is one of, or a combination of two or more of sodium chloride, sodium dihydrogen phosphate, sodium carbonate, sodium citrate, sodium acetate, and sodium silicate.

6. A preparation method of the texturing additive for improving the efficiency of the solar cell according to claim 1, comprising the following steps:
according to the percentages by mass, adding the primary nucleating agent, the secondary nucleating agent, the dispersant, and the etching inhibitor to the water, and uniformly mixing under stirring to obtain the texturing additive.

7. A method of using the texturing additive according to claim 1 in texturing of a silicon wafer.

8. The method according to claim 7, wherein the texturing additive is used in a texturing reaction of the silicon wafer to improve efficiency of the solar cell.

9. The method according to claim 8, wherein the method comprises:
step (1) dissolving a pure alkali in water and uniformly mixing to obtain an alkali solution, and adding the texturing additive to the alkali solution and uniformly mixing to formulate a mixed texturing agent; and
step (2) immersing the silicon wafer in the mixed texturing agent for the texturing reaction.

10. The method according to claim 9, wherein
in the step (1), the pure alkali is selected from a group consisting of NaOH and KOH; a mass concentration of the alkali solution is 0.5% to 1%; and a mass ratio of the texturing additive to the alkali solution is (0.3 to 0.8):100; and
in the step (2), the texturing reaction is conducted at a temperature controlled between 75° C. and 85° C. for 350 s to 450 s.

11. The texturing additive for improving the efficiency of the solar cell according to claim 3, wherein the R₁, the R₂, the R₃, the R₄, and the R₅ are each independently selected from a group consisting of H, halogen, C₁-C₃ alkyl, —NH₂, —CONH₂, —CHO, —NHNH₂, —SO₃R₆, —OR₇, and —COOR₈; the R₆ is selected from a group consisting of H, Na, and K; the R₇ and the R₈ are each independently selected from a group consisting of H, Na, K, and C₁-C₂ alkyl; at least three of the R₁, the R₂, the R₃, the R₄, and the R₅ are H.

12. The texturing additive for improving the efficiency of the solar cell according to claim 5, wherein the polysaccharide-based compound is selected from a group consisting of maltose, carrageenan, starch, lactose, cellulose, chitin, xanthan gum, inulin, polymannose, and polyxylose.
